(19) United States
(12) Patent Application Publication
(10) Pub. No.: US 2025/0311361 A1
(43) Pub. Date: Oct. 2, 2025

(54) SEMICONDUCTOR DEVICE

(71) Applicant: Taiwan Semiconductor Manufacturing Company, Ltd., Hsinchu (TW)

(72) Inventors: Yong-Sheng Huang, Hsinchu (TW); Jhih-Bin Chen, Hsinchu (TW); Chao-Hsi Wu, Taichung City (TW)

(73) Assignee: Taiwan Semiconductor Manufacturing Company, Ltd., Hsinchu (TW)

(21) Appl. No.: 18/624,151

(22) Filed: Apr. 2, 2024

(51) Int. Cl. H01L 29/40; H01L 29/06; H01L 29/66; H01L 29/78

(52) U.S. Cl. CPC H10D 64/111; H10D 30/0281; H10D 30/65; H10D 62/116

(57) ABSTRACT

A semiconductor device including a semiconductor substrate, an isolation structure, a first gate structure and a second gate structure is provided. The semiconductor substrate includes a source doped region and a drain doped region laterally spaced apart from the source doped region. The isolation structure is embedded in the semiconductor substrate, and the isolation structure is disposed between the source doped region and the drain doped region. The first gate structure is disposed over a region of the semiconductor substrate, and the region of the semiconductor substrate is between the isolation structure and the source doped region. The second gate structure is disposed on the isolation structure, wherein the second gate structure is laterally spaced apart from the first gate structure, and the second gate structure includes a main portion and at least one protruding portion extending from the main portion toward the drain doped region.

### BACKGROUND

The electronics Interest and development in lateral diffused metal-oxide semiconductor (LDMOS) devices have been growing because the LDMOS devices can be easily integrated with low voltage circuitry to form high voltage integrated circuits (HVICs) and/or smart power management integrated circuits (SPMICs). In the currently fabricated LDMOS devices, an excess of hot carriers may degrade reliability as well as induce high leakage current. Thus, how to improve the reliability issue of the LDMOS devices is important in this industry.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 5 schematically illustrate the cross-sectional views of intermediate stages in the fabrication of a lateral diffused metal-oxide semiconductor (LDMOS) device in accordance with some embodiments of the present disclosure.

FIG. 6 schematically illustrates a top view of an intermediate stage as shown in FIG. 3 in accordance with some embodiments of the present disclosure.

FIG. 7 schematically illustrates a top view of an intermediate stage as shown in FIG. 4 in accordance with some embodiments of the present disclosure.

FIG. 8 schematically illustrates a top view of an intermediate stage as shown in FIG. 4 in accordance with some other embodiments of the present disclosure.

FIG. 9 schematically illustrates a top view of an intermediate stage as shown in FIG. 4 in accordance with some alternative embodiments of the present disclosure.

FIG. 10 schematically illustrate the distribution of electric field under the second isolation structure 170b shown in FIG. 4 if the second gate structure 190 includes no protruding portion.

FIG. 11 schematically illustrate the distribution of electric field under the second isolation structure 170b shown in FIG. 4 when the second gate structure 190 includes a pair of protruding portions.

### DETAILED DESCRIPTION

It is to be understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

The present disclosure relates to semiconductor devices and a method for fabricating the same. The semiconductor devices may be, but not limited to, an LDMOS device in a bipolar complementary metal-oxide semiconductor (Bipolar CMOS), diffusion metal-oxide semiconductor (DMOS) devices (Bipolar CMOS DMOS (BCD) devices), for example. In other words, the LDMOS devices are so-called LDMOS field effect transistors (LDMOS FETs) or other suitable high-power field effect transistors (FETs).

An increase in operating voltages of the LDMOS FETs is resulting in higher instances of breakdown of the FETs. The drain to source voltage at which such breakdown occurs is referred to as the drain to source breakdown voltage (V_{bd}) of the LDMOS FETs. In the LDMOS FETs, one of the root causes of the breakdown caused by a high drain to source voltage is the impact ionization at the corner of the gate structure and the isolation structure. High electric field generated in proximity to the corner of the gate structure and the isolation structure can increase the impact ionization at the corner. The impact ionization can increase dramatically with the increase in the drain to source voltage and results in avalanche breakdown in the LDMOS FETs. The following described embodiments of the present disclosure provide an LDMOS FETs with novel design of gate structure so as to enhance the drain to source breakdown voltage (V_{bd}) of the LDMOS FETs.

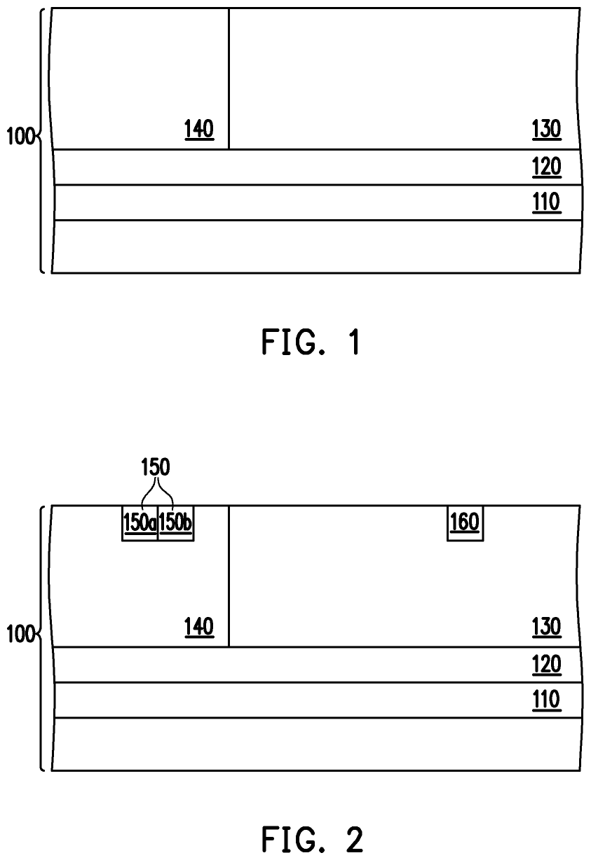

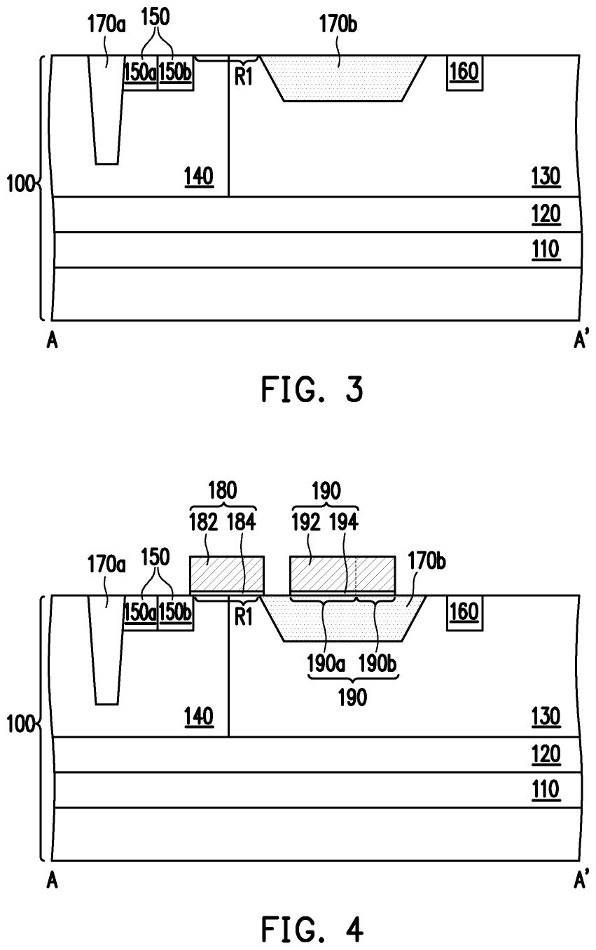

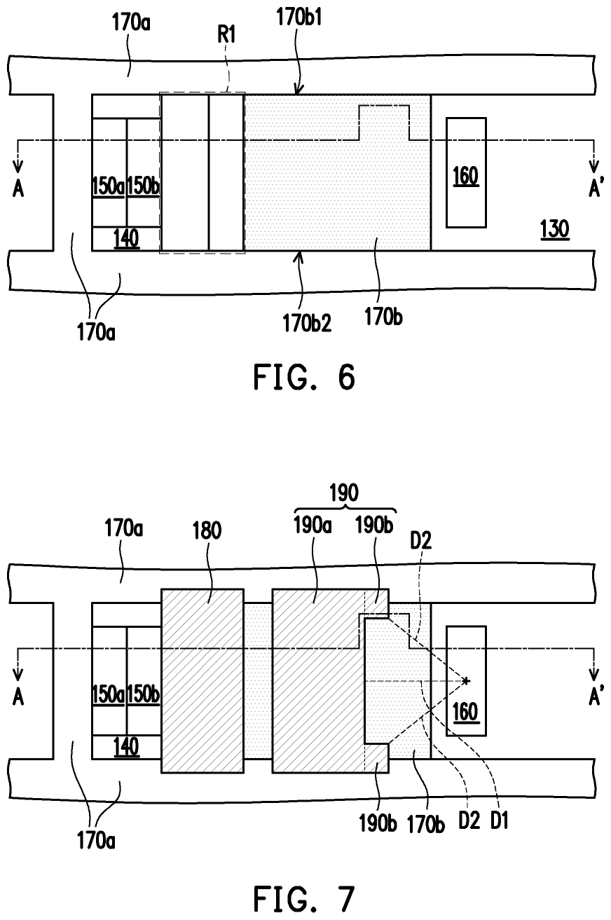

FIG. 1 through FIG. 5 schematically illustrate the cross-sectional views of intermediate stages in the fabrication of an n-type lateral diffused metal-oxide semiconductor (n-type LDMOS) device in accordance with some embodiments of the present disclosure; FIG. 6 schematically illustrates a top view of an intermediate stage as shown in FIG. 3 in accordance with some embodiments of the present disclosure; and FIG. 7 schematically illustrates a top view of an intermediate stage as shown in FIG. 4 in accordance with some embodiments of the present disclosure.

Referring to FIG. 1, a semiconductor substrate 100 is provided. In some embodiments, the semiconductor substrate 100 is a silicon wafer. In some embodiments, the semiconductor substrate 100 is a bulk mono-crystalline silicon substrate, a layer of silicon on a silicon wafer, a layer of a silicon-on-insulator (SOI) wafer, or a layer of a germanium-on-insulator (GeOI) wafer. In some alternative embodiments, other semiconductor materials, such as silicon germanium, germanium, gallium arsenide, indium arsenide, indium gallium arsenide, indium antimonide or others, can be used with the semiconductor wafer.

A first deep well region 110 of first conductivity type and a second deep well region 120 of second conductivity type are formed in the semiconductor substrate 100. The second deep well region 120 is formed on the first deep well region 110, the second deep well region 120 interfaces the first deep well region 110, and the bottom portion of the second deep well region 120 abuts the top portion of the first deep well region 110. The first deep well region 110 may be a deep n-type well region, and the second deep well region 120 may be a deep p-type well region formed over the first deep well region 110. The first deep well region 110 and the second deep well region 120 are buried in the semiconductor substrate 100. In other words, the first deep well region 110 and the second deep well region 120 are not revealed from the top surface of the semiconductor substrate 100. The first deep well region 110 and the second deep well region 120 may serve as bottom isolation regions in the semiconductor substrate 100. The first deep well region 110 may be formed in the semiconductor substrate 100 by a first ion implantation process followed by a first annealing process, and the second deep well region 120 may be formed in the semiconductor substrate 100 by a second ion implantation process followed by a second annealing process. For example, n-type impurities or n-type dopants, such as phosphorus or arsenic, and/or combinations thereof are implanted to form the first deep well region 110, and p-type impurities or p-type dopants, such as boron or BF₂ are implanted to form the second deep well region 120. The first ion implantation process and the second ion implantation process are respectively performed to implant impurities into different regions located at different depths or level heights, and the first annealing process and the second annealing process are performed so as to drive the diffusion of the implanted impurities or dopants in the semiconductor substrate 100.

A drift region 130 of first conductivity type and a high voltage well region 140 of second conductivity type are formed within the semiconductor substrate 100. The process sequence for forming the drift region 130 and the high voltage well region 140 is not limited in the present disclosure. In some embodiments, the formation of the drift region 130 is performed prior to the formation of the high voltage well region 140. In some alternative embodiments, the formation of the drift region 130 is performed after the formation of the high voltage well region 140. The drift region 130 and the high voltage well region 140 are located at the same depth or level height. The drift region 130 laterally abuts the high voltage well region 140. The drift region 130 and the high voltage well region 140 are formed on the second deep well region 120. The drift region 130 and the high voltage well region 140 interfaces the second deep well region 120, and the bottom portions of the drift region 130 and the high voltage well region 140 abut the top portion of the second deep well region 120. The drift region 130 may be a n-type drift region, and the high voltage well region 140 may be a deep p-type well region formed next to the n-type drift region. The drift region 130 may be formed in the semiconductor substrate 100 by a third ion implantation process followed by a third annealing process, and the high voltage well region 140 may be formed in the semiconductor substrate 100 by a fourth ion implantation process followed by a fourth annealing process. For example, n-type impurities or dopants, such as phosphorus or arsenic, and/or combinations thereof are implanted to form the drift region 130, and p-type impurities or dopants, such as boron or BF₂ are implanted to form the high voltage well region 140. The third ion implantation process and the fourth ion implantation process are respectively performed to implant impurities into different regions located at the same depth or level height, and the third annealing process and the fourth annealing process are performed so as to drive the diffusion of the implanted impurities or dopants in the semiconductor substrate 100.

As illustrated in FIG. 1, a portion (e.g., the right-side portion) of the second deep well region 120 is located between the first deep well region 110 and the drift region 130, and another portion (e.g., the left-side portion) of the second deep well region 120 is located between the first deep well region 110 and the high voltage well region 140. The drift region 130 and the high voltage well region 140 are revealed from the top surface of the semiconductor substrate 100 at this stage. Furthermore, the drift region 130 and the high voltage well region 140 extend downwardly from the top surface of the semiconductor substrate 100 to the second deep well region 120.

Referring to FIG. 2, after forming the drift region 130 and the high voltage well region 140, a source doped region 150 and a drain doped region 160 are formed in the semiconductor substrate 100, wherein the drain doped region 160 is laterally spaced apart from the source doped region 150. The source doped region 150 is formed within the high voltage well region 140, and the drain doped region 160 is formed within the drift region 130. The source doped region 150 and the drain doped region 160 are revealed from the top surface of the semiconductor substrate 100 at this stage. The doped depth of the source doped region 150 and the drain doped region 160 is shallower than the doped depth of the drift region 130 and the high voltage well region 140. The source doped region 150 and the drain doped region 160 are vertically spaced apart from the second deep well region 120 by the doped depth of the drift region 130 and the high voltage well region 140.

The source doped region 150 may include a first heavily doped region 150a of first conductivity type and a second heavily doped region 150b of second conductivity type, the first heavily doped region 150a may be a p-type heavily doped region (i.e., a p+ doped region), and the second heavily doped region 150b may be an n-type heavily doped region (i.e., an n+ doped region). The second heavily doped region 150b is laterally between the first heavily doped region 150a and the drain doped region 160. The second heavily doped region 150b laterally abuts the first heavily doped region 150a.

The drain doped region 160 and the second heavily doped region 150b may be formed in the semiconductor substrate 100 by a fifth ion implantation process followed by a fifth annealing process, and the first heavily doped region 150a may be formed in the semiconductor substrate 100 by a sixth ion implantation process followed by a sixth annealing process. For example, n-type impurities or dopants, such as phosphorus or arsenic, and/or combinations thereof are implanted to form the drain doped region 160 and second heavily doped region 150b, and p-type impurities or dopants, such as boron or BF₂ are implanted to form the first heavily doped region 150a. The fifth ion implantation process and the sixth ion implantation process are respectively performed to implant impurities into different regions located at the same depth or level height, and the fifth annealing process and the sixth annealing process are performed so as to drive the diffusion of the implanted impurities or dopants in the semiconductor substrate 100.

In some alternative embodiments, the drain doped region 160 and second heavily doped region 150b are formed in the semiconductor substrate 100 by different ion implantation process followed by an annealing process, and the impurities and the dopants in the drain doped region 160 and second heavily doped region 150b are different from or substantially identical to each other.

Referring to FIG. 3 and FIG. 6, the cross-sectional view illustrated in FIG. 3 is cut along the cross-section line A-A′ shown in FIG. 6. As illustrated in FIG. 3 and FIG. 6, a first isolation structure 170a is formed in the high voltage well region 140 so as to define an active region within the semiconductor substrate 100. A second isolation structure 170b is then formed in the drift region 130 which is laterally surrounded by the first isolation structure 170a. The above-mentioned active region defined by the first isolation structure 170a is a so-called oxide-defined (OD) region surrounded by the first isolation structure 170a. The source doped region 150, the drain doped region 160 and the second isolation structure 170b are distributed in the active region or the OD region defined by the first isolation structure 170a. The first isolation structure 170a and the second isolation structure 170b may be shallow trench isolation structures with different thicknesses. The first isolation structure 170a may be formed by forming a shallow trench in the high voltage well region 140, filling the shallow trench with TEOS-formed oxide material, and removing (e.g., polishing) the excess TEOS-formed oxide material outside the shallow trench. The second isolation structure 170b may be formed by forming an ultra-shallow trench in the drift region 130, filling the ultra-shallow trench with TEOS-formed oxide material, and removing (e.g., polishing) the excess TEOS-formed oxide material outside the ultra-shallow trench. The process sequence for forming the first isolation structure 170a and the second isolation structure 170b is not limited in the present disclosure. In some embodiments, the formation of the first isolation structure 170a is performed prior to the formation of the second isolation structure 170b. In some alternative embodiments, the formation of the first isolation structure 170a is performed after the formation of the second isolation structure 170b.

In some embodiments, the first isolation structure 170a includes a shallow trench isolation (STI) structure, and the second isolation structure 170b includes an ultra-shallow trench isolation (USTI) structure. The thickness of the first isolation structure 170a is greater than the thickness of the second isolation structure 170b, as shown in FIG. 3. The aspect ratio of the first isolation structure 170a is greater than the aspect ratio of the second isolation structure 170b. As shown in FIG. 6, the first isolation structure 170a is formed to laterally surround the source doped region 150, the drain doped region 160 and the second isolation structure 170b. The first isolation structure 170a and second isolation structure 170b are embedded in the semiconductor substrate 100, and the second isolation structure 170b is disposed between the source doped region 150 and the drain doped region 160 laterally. Furthermore, from the top view illustrated in FIG. 6, the second isolation structure 170b includes an upper edge 170b1 and a lower edge 170b2 opposite to the upper edge 170b1, wherein the upper edge 170b1 of the second isolation structure 170b and the lower edge 170b2 of the second isolation structure 170b are in contact with the first isolation structure 170a.

As illustrated in FIG. 3 and FIG. 6, a portion of the first isolation structure 170a laterally abuts the first heavily doped region 150a among the source doped region 150, and the second isolation structure 170b is laterally spaced apart from the source doped region 150 and the drain doped region 160. For example, the second isolation structure 170b is laterally spaced apart from the source doped region 150 by a region R1 of the semiconductor substrate 100, and the second isolation structure 170b is laterally spaced apart from the drain doped region 160 by a portion of the drift region 130. The region R1 of the semiconductor substrate 100 includes a left region and a right region abutting the left region, wherein the left region of the region R1 may be or include a portion of high voltage well region 140, the right region of the region R1 may be or include a portion of the drift portion 130. The region R1 of the semiconductor substrate 100 may serve a channel region between the source doped region 150 and the second isolation structure 170b. Furthermore, in some embodiments, the top surface of the first isolation structure 170a and/or the top surface of the second isolation structure 170b substantially levels with the top surface of the semiconductor substrate 100, as illustrated in FIG. 3. In some other embodiments, the top surface of the first isolation structure 170a and/or the top surface of the second isolation structure 170b are slightly higher than the top surface of the semiconductor substrate 100, not shown in figures.

Referring to FIG. 4 and FIG. 7, the cross-sectional view illustrated in FIG. 4 is cut along the cross-section line A-A′ shown in FIG. 7. As illustrated in FIG. 4 and FIG. 7, a first gate structure 180 and a second gate structure 190 are formed over the top surface of the semiconductor substrate 100, wherein the second gate structure 190 is spaced apart from the first gate structure 180. The first gate structure 180 is formed to at least cover the region R1 of the semiconductor substrate 100, a portion of the first heavily doped region 150a and a portion of the second isolation structure 170b. The above-mentioned portion of the first heavily doped region 150a (e.g., the right-side edge of the first heavily doped region 150a) and the above-mentioned portion of the second isolation structure 170b (e.g., the left-side edge of the second isolation structure 170b) may abut the region R1 of the semiconductor substrate 100 laterally. The region R1 of the semiconductor substrate 100 which is covered by the first gate structure 180 is laterally located between the second isolation structure 170b and the first heavily doped region 150a among the source doped region 150. Furthermore, the top surface of the second isolation structure 170b are covered by and in contact with the first gate structure 180 and the second gate structure 190.

As illustrated in FIG. 6 and FIG. 7, there is a boundary existing between the region R1 of the semiconductor substrate 100 and the second isolation structure 170b, and the boundary between the region R1 of the semiconductor substrate 100 and the second isolation structure 170b are covered by the first gate structure 180. The left-side edge of the second isolation structure 170b interfaces with the right-side edge of the region R1 to form the boundary between the region R1 of the semiconductor substrate 100 and the second isolation structure 170b.

Furthermore, there is a boundary existing between the first isolation structure 170a (e.g., the first shallow trench isolation structure) and the second isolation structure 170b (e.g., the second shallow trench isolation structure), and portions of the boundary between the first isolation structure 170a and the second isolation structure 170b are covered by the first gate structure 180 and the second gate structure 190. Both of the upper edge 170b1 of the second isolation structure 170b and the lower edge 170b2 of the second isolation structure 170b may interface with the first isolation structure 170a such that the boundary between the first isolation structure 170a and the second isolation structure 170b is formed.

The first gate structure 180 is laterally spaced apart from and electrically insulated from the second gate structure 190. The first gate structure 180 and the second gate structure 190 are not electrically connected to each other. In other words, different control signals may be applied to the first gate structure 180 and the second gate structure 190 such that the first gate structure 180 and the second gate structure 190 can be driven individually through said different control signals (e.g., different voltage sources). The first gate structure 180 functions as a control gate for switching the on/off state of the channel region R1, and the second gate structure 190 functions as a split gate or an auxiliary gate for enhancing or optimizing the electric field distributed under the second isolation structure 170b.

As illustrated in FIG. 7, the first gate structure 180 is in contact with the top surface of the semiconductor substrate 100, the top surface of the first isolation structure 170a and the top surface of the second isolation structure 170b. The second gate structure 190 is in contact with the top surface of the first isolation structure 170a and the top surface of the second isolation structure 170b. Since the second gate structure 190 lands on the first isolation structure 170a and the second isolation structure 170b, the second gate structure 190 is not physically in contact with the top surface of the semiconductor substrate 100.

As illustrated in FIG. 4, the first gate structure 180 includes a first gate electrode 182 and a first gate dielectric layer 184 disposed between the first gate electrode 182 and the region R1 of the semiconductor substrate 100, and the second gate structure 190 includes a second gate electrode 192 and a second gate dielectric layer 194 disposed between the second gate electrode 192 and the second isolation structure 170b. In some embodiments, the first gate electrode 182 and the second gate electrode 190 include poly-silicon gate electrodes. In some other embodiments, the first gate electrode 182 and the second gate electrode 190 include metallic gate electrodes.

As illustrated in FIG. 4 and FIG. 7, the second gate structure 190 includes a main portion 190a and at least one protruding portion 190b laterally extending from the main portion 190a toward the drain doped region 160. In the present embodiments, the at least one protruding portion 190b includes a pair of protruding portions 190b, the main portion 190a is disposed between the pair of protruding portions 190b and the first gate structure 180. The pair of protruding portions 190b extend from opposite ends of the main portion 190a. The extending direction of the main portion 190a substantially parallels to the extending direction of the first gate structure 180, and the extending direction of the pair of protruding portions 190b is different from the extending direction of the main portion 190a.

In some embodiments, a first minimum lateral distance D1 between the main portion 190a and a center of the drain doped region 160 substantially equals to a second minimum lateral distance D2 between the pair of protruding portions 190b and the center of the drain doped region 160. In some other embodiments, a first minimum lateral distance D1 between the main portion 190a and a center of the drain doped region 160 is greater than a second minimum lateral distance D2 between the pair of protruding portions 190b and the center of the drain doped region 160. The first minimum lateral distance D1 and the second minimum lateral distance D2 may be determined based on design rule of the fabrication of the LDMOS device (e.g., an LDMOS FET). The first minimum lateral distance D1 and the second minimum lateral distance D2 define the keep-out zone (KOZ) between the second gate structure 190 and the drain doped region 160.

The pair of protruding portions 190b are of rectangular shape, as illustrated in FIG. 7. In some embodiments, an area occupied by the pair of protruding portions 190b is about 20% of an area occupied by the main portion 190a. The protruding portions 190b extending from the main portion 190a may increase an overlapping area between the second gate structure 190 and the second isolation structure 170b such that the distribution of electric field under the second isolation structure 170b can be broadened. Accordingly, the drain to source breakdown voltage (V_{bd}) of the LDMOS device (e.g., LDMOS FET) may be enhanced due to the broadened distribution of electric field.

As described above, the LDMOS device (e.g., LDMOS FET) is fabricated by a series of front end of line (FEOL) process steps.

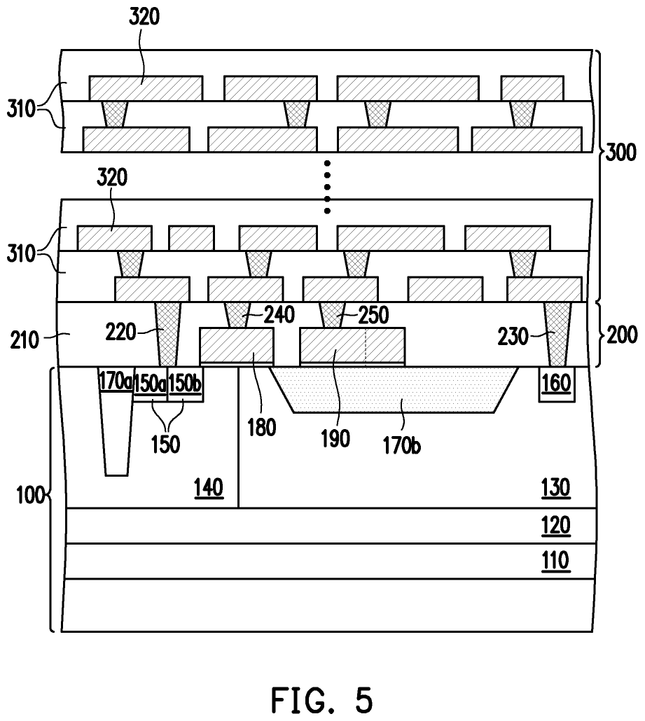

Referring to FIG. 5, a series of middle end of line (MEOL) process steps are performed to form a middle-end interconnect structure 200. The series of middle end of line (MEOL) process steps are performed to the middle-end interconnect structure 200 including a dielectric layer 210, a source contact 220, a drain contact 230, a first gate contact 240 and a second gate contact 250. The dielectric layer of the middle-end interconnect structure 200 covers the semiconductor substrate 100, the first gate structure and the second gate structure. The source contact 220, the drain contact 230, the first gate contact 240 and the second gate contact 250 are formed in the dielectric layer 210. The source contact 220, the drain contact 230, the first gate contact 240 and the second gate contact 250 penetrate through the dielectric layer 210. The source contact 220 lands on and is electrically connected to the source doped region 150, the drain contact 230 lands on and electrically connected to the drain doped region 160, the first gate contact 240 lands on and electrically connected to the first gate structure 180, and the second gate contact 250 lands on and electrically connected to the second gate structure 190. Furthermore, in some embodiments, as shown in FIG. 5, the source contact 220 lands on and is electrically connected to the first heavily doped region 150a and the second heavily doped region 150b simultaneously. In some other embodiments, not shown in figures, the source contact 220 includes a pair of conductive plugs or metallic posts, and each one of the pair of conductive plugs lands on and electrically connected to one of the first heavily doped region 150a and the second heavily doped region 150b, respectively.

After performing the series of middle end of line (MEOL) process steps, a series of back end of line (BEOL) process steps are performed to form a back-end interconnect structure 300 over the middle-end interconnect structure 200. The series of back end of line (BEOL) process steps are performed to the back-end interconnect structure 300 including stacked dielectric layers 310 and multiple layers of interconnect wirings 320 embedded in the stacked dielectric layers 310. The bottommost interconnect wiring layer among the multiple layers of interconnect wirings 320 are electrically connected to the source doped region 150, the drain doped region 160, the first gate structure 180 and the second gate structure 190 through the source contact 220, the drain contact 230, the first gate contact 240 and the second gate contact 250, respectively.

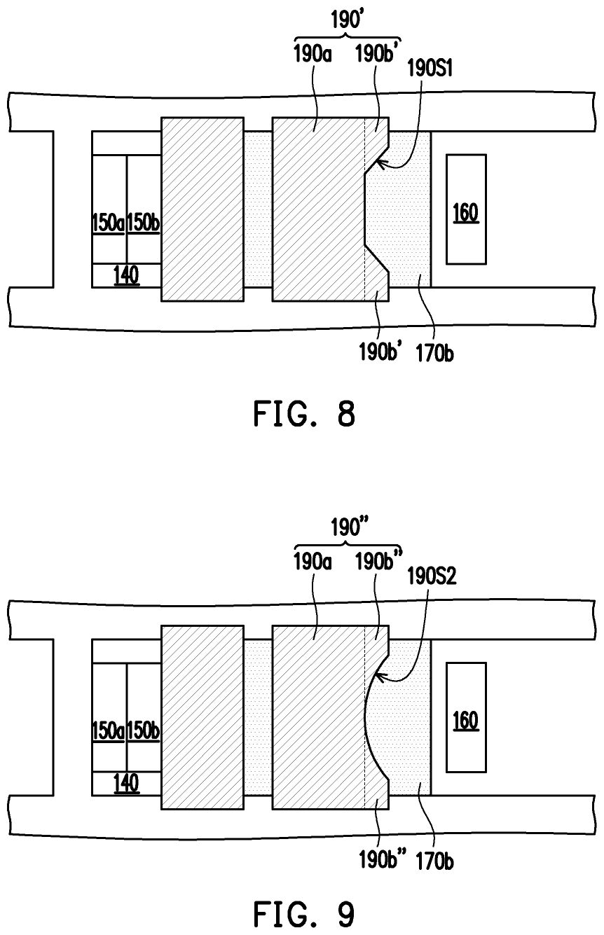

FIG. 8 schematically illustrates a top view of an intermediate stage as shown in FIG. 4 in accordance with some other embodiments of the present disclosure.

Referring to FIG. 7 and FIG. 8, the LDMOS device (e.g., LDMOS FET) illustrated in FIG. 8 is similar with the LDMOS device (e.g., LDMOS FET) illustrated in FIG. 7 except that each of the pair of protruding portions 190b′ of the second gate structure 190′ are of trapezium shape. As illustrated in FIG. 8, the pair of protruding portions 190b′ of the second gate structure 190′ may include a pair of inclined and planar sidewalls 190S1.

FIG. 9 schematically illustrates a top view of an intermediate stage as shown in FIG. 4 in accordance with some alternative embodiments of the present disclosure.

Referring to FIG. 7 and FIG. 9, the LDMOS device (e.g., LDMOS FET) illustrated in FIG. 9 is similar with the LDMOS device (e.g., LDMOS FET) illustrated in FIG. 7 except that each of the pair of protruding portions 190b″ of the second gate structure 190″ are of irregular shape. As illustrated in FIG. 9, the pair of protruding portions 190b″ of the second gate structure 190″ may include a curved sidewall 190S2.

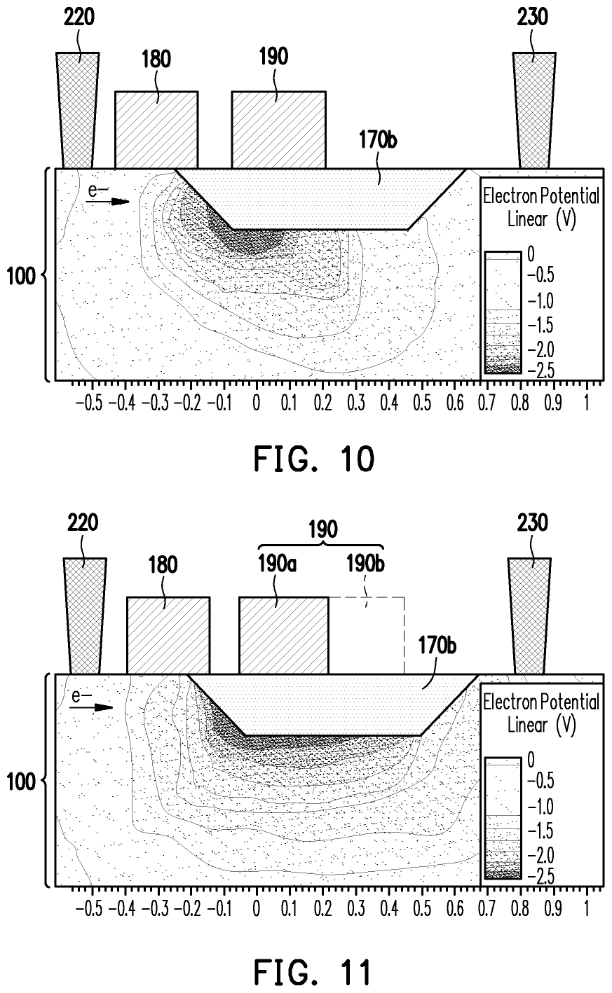

FIG. 10 schematically illustrate the distribution of electric field under the second isolation structure 170b shown in FIG. 4 if the second gate structure 190 includes no protruding portion, and FIG. 11 schematically illustrate the distribution of electric field under the second isolation structure 170b shown in FIG. 4 when the second gate structure 190 includes a pair of protruding portions.

As illustrated in FIG. 10, a gate voltage of about 2.5 Volts is applied to the first gate structure 180, a drain voltage of about 20 Volts is applied to the drain doped region 160, the source doped region 150 is electrically grounded, and a gate voltage of about 2.5-3.3 Volts is applied to the second gate structure 190; under this condition, the distribution of electric field under the second isolation structure 170b converges in a region located below the second gate structure 190 including no protruding portion. Punch-through may easily occur in the region where the distribution of electric field converges. As illustrated in FIG. 11, a gate voltage of about 2.5 Volts is applied to the first gate structure 180, a drain voltage of about 20 Volts is applied to the drain doped region 160, the source doped region 150 is electrically grounded, and a gate voltage of about 2.5-3.3 Volts is applied to the second gate structure 190; under this condition, the distribution of electric field under the second isolation structure 170b is broadened by the pair of protruding portions 190b of the second gate structure 190. Accordingly, punch-through generated under the second isolation structure 170b may be reduced. Based on the simulations shown in FIG. 10 and FIG. 11, the protruding portion design of the split gate (i.e., the second gate structure) may enhance the distribution of the electric field under the second isolation structure 170b such that the drift region 130 can function better and the LDMOS device may operate more reliably.

In the above-mentioned embodiments, through properly design of the split gate in the LDMOS FETs, the breakdown voltage (V_{bd}) of the LDMOS FETs may be enhanced, and accordingly, the LDMOS FETs is capable of sustaining high voltage reliably.

In accordance with some embodiments of the present disclosure, a semiconductor device including a semiconductor substrate, an isolation structure, a first gate structure and a second gate structure is provided. The semiconductor substrate includes a source doped region and a drain doped region laterally spaced apart from the source doped region. The isolation structure is embedded in the semiconductor substrate, and the isolation structure is disposed between the source doped region and the drain doped region. The first gate structure is disposed over a region of the semiconductor substrate, and the region of the semiconductor substrate is between the isolation structure and the source doped region. The second gate structure is disposed on the isolation structure, wherein the second gate structure is laterally spaced apart from the first gate structure, and the second gate structure comprises a main portion and at least one protruding portion extending from the main portion toward the drain doped region. In some embodiments, the isolation structure is laterally spaced apart from the source doped region and the drain doped region. In some embodiments, the first gate structure covers the region of the semiconductor substrate, the source doped region and the isolation structure. In some embodiments, the isolation structure is in contact with the first gate structure and the second gate structure. In some embodiments, the first gate structure is electrically insulated from the second gate structure. In some embodiments, a top surface of the isolation structure substantially levels with a top surface of the semiconductor substrate, the first gate structure is in contact with the top surface of the semiconductor substrate and the top surface of the isolation structure, and the second gate structure is in contact with the top surface of the isolation structure. In some embodiments, a first minimum lateral distance between the main portion and a center of the drain doped region substantially equals to a second minimum lateral distance between the at least one protruding portion and the center of the drain doped region. In some embodiments, a first minimum lateral distance between the main portion and a center of the drain doped region is greater than a second minimum lateral distance between the at least one protruding portion and the center of the drain doped region.

In accordance with some embodiments of the present disclosure, a semiconductor device including a semiconductor substrate, an isolation structure, a first gate structure and a second gate structure is provided. The semiconductor substrate includes a source doped region and a drain doped region laterally spaced apart from the source doped region. The isolation structure is embedded in the semiconductor substrate, and the isolation structure is disposed between the source doped region and the drain doped region. The first gate structure is disposed over the semiconductor substrate. The second gate structure is disposed on the isolation structure, wherein the second gate structure is electrically insulated from the first gate structure, the second gate structure comprises a main portion and a pair of protruding portions, and the main portion is between the pair of protruding portions and the first gate structure. In some embodiments, an area occupied by the pair of protruding portions is about 20% of an area occupied by the main portion. In some embodiments, a first minimum lateral distance between the main portion and a center of the drain doped region substantially equals to a second minimum lateral distance between the pair of protruding portions and the center of the drain doped region. In some embodiments, a first minimum lateral distance between the main portion and a center of the drain doped region is greater than a second minimum lateral distance between the pair of protruding portions and the center of the drain doped region. In some embodiments, the first gate structure and the second gate structure are electrically connected to different voltage sources. In some embodiments, a boundary exists between the semiconductor substrate and the isolation structure, and the boundary between the semiconductor substrate and the isolation structure are covered by the first gate structure.

In accordance with some embodiments of the present disclosure, a semiconductor device including a semiconductor substrate, a first shallow trench isolation structure, a second shallow trench isolation, a first gate structure and a second gate structure is provided. The semiconductor substrate includes a source doped region and a drain doped region laterally spaced apart from the source doped region. The first shallow trench isolation structure is embedded in the semiconductor substrate, wherein an active region is defined in the semiconductor substrate by the first shallow trench isolation structure, and the source doped region and the drain doped region are distributed in the active region. The second shallow trench isolation structure is embedded in the semiconductor substrate, wherein the second shallow trench isolation structure is disposed between the source doped region and the drain doped region, and the first shallow trench isolation structure are thicker than the second shallow trench isolation structure. The first gate structure is disposed on the semiconductor substrate. The second gate structure is disposed on the second shallow trench isolation structure, wherein the second gate structure comprises a main portion and a pair of protruding portions, an extending direction of the main portion substantially parallels to an extending direction of the first gate structure, and an extending direction of the pair of protruding portions is different from the extending direction of the main portion. In some embodiments, an area occupied by the pair of protruding portions is about 20% of an area occupied by the main portion. In some embodiments, a first minimum lateral distance between the main portion and a center of the drain doped region substantially equals to a second minimum lateral distance between the pair of protruding portions and the center of the drain doped region. In some embodiments, a first minimum lateral distance between the main portion and a center of the drain doped region is greater than a second minimum lateral distance between the pair of protruding portions and the center of the drain doped region. In some embodiments, the first gate structure is electrically insulated from the second gate structure. In some embodiments, a boundary exists between the first shallow trench isolation structure and the second shallow trench isolation structure, and portions of the boundary between the first shallow trench isolation structure and the second shallow trench isolation structure are covered by the first gate structure and the second gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor substrate comprising a source doped region and a drain doped region laterally spaced apart from the source doped region;
an isolation structure embedded in the semiconductor substrate, and the isolation structure being disposed between the source doped region and the drain doped region;
a first gate structure disposed over a region of the semiconductor substrate, and the region of the semiconductor substrate is between the isolation structure and the source doped region; and
a second gate structure disposed on the isolation structure, wherein the second gate structure is laterally spaced apart from the first gate structure, and the second gate structure comprises a main portion and at least one protruding portion extending from the main portion toward the drain doped region.

2. The semiconductor device of claim 1, wherein the isolation structure is laterally spaced apart from the source doped region and the drain doped region.

3. The semiconductor device of claim 1, wherein the first gate structure covers the region of the semiconductor substrate, the source doped region and the isolation structure.

4. The semiconductor device of claim 1, wherein the isolation structure is in contact with the first gate structure and the second gate structure.

5. The semiconductor device of claim 1, wherein the first gate structure is electrically insulated from the second gate structure.

6. The semiconductor device of claim 1, wherein a top surface of the isolation structure substantially levels with a top surface of the semiconductor substrate, the first gate structure is in contact with the top surface of the semiconductor substrate and the top surface of the isolation structure, and the second gate structure is in contact with the top surface of the isolation structure.

7. The semiconductor device of claim 1, wherein a first minimum lateral distance between the main portion and a center of the drain doped region substantially equals to a second minimum lateral distance between the at least one protruding portion and the center of the drain doped region.

8. The semiconductor device of claim 1, wherein a first minimum lateral distance between the main portion and a center of the drain doped region is greater than a second minimum lateral distance between the at least one protruding portion and the center of the drain doped region.

9. A semiconductor device, comprising:
a semiconductor substrate comprising a source doped region and a drain doped region laterally spaced apart from the source doped region;
an isolation structure embedded in the semiconductor substrate, and the isolation structure being disposed between the source doped region and the drain doped region;
a first gate structure disposed over the semiconductor substrate; and
a second gate structure disposed on the isolation structure, wherein the second gate structure is electrically insulated from the first gate structure, the second gate structure comprises a main portion and a pair of protruding portions, and the main portion is between the pair of protruding portions and the first gate structure.

10. The semiconductor device of claim 9, wherein an area occupied by the pair of protruding portions is about 20% of an area occupied by the main portion.

11. The semiconductor device of claim 9, wherein a first minimum lateral distance between the main portion and a center of the drain doped region substantially equals to a second minimum lateral distance between the pair of protruding portions and the center of the drain doped region.

12. The semiconductor device of claim 9, wherein a first minimum lateral distance between the main portion and a center of the drain doped region is greater than a second minimum lateral distance between the pair of protruding portions and the center of the drain doped region.

13. The semiconductor device of claim 9, wherein the first gate structure and the second gate structure are electrically connected to different voltage sources.

14. The semiconductor device of claim 9, wherein a boundary exists between the semiconductor substrate and the isolation structure, and the boundary between the semiconductor substrate and the isolation structure are covered by the first gate structure.

15. A semiconductor device, comprising:
a semiconductor substrate comprising a source doped region and a drain doped region laterally spaced apart from the source doped region;
a first shallow trench isolation structure embedded in the semiconductor substrate, wherein an active region is defined in the semiconductor substrate by the first shallow trench isolation structure, and the source doped region and the drain doped region are distributed in the active region;
a second shallow trench isolation structure embedded in the semiconductor substrate, wherein the second shallow trench isolation structure is disposed between the source doped region and the drain doped region, and the first shallow trench isolation structure are thicker than the second shallow trench isolation structure;
a first gate structure disposed on the semiconductor substrate; and
a second gate structure disposed on the second shallow trench isolation structure, wherein the second gate structure comprises a main portion and a pair of protruding portions, an extending direction of the main portion substantially parallels to an extending direction of the first gate structure, and an extending direction of the pair of protruding portions is different from the extending direction of the main portion.

16. The semiconductor device of claim 15, wherein an area occupied by the pair of protruding portions is about 20% of an area occupied by the main portion.

17. The semiconductor device of claim 15, wherein a first minimum lateral distance between the main portion and a center of the drain doped region substantially equals to a second minimum lateral distance between the pair of protruding portions and the center of the drain doped region.

18. The semiconductor device of claim 15, wherein a first minimum lateral distance between the main portion and a center of the drain doped region is greater than a second minimum lateral distance between the pair of protruding portions and the center of the drain doped region.

19. The semiconductor device of claim 15, wherein the first gate structure is electrically insulated from the second gate structure.

20. The semiconductor device of claim 15, wherein a boundary exists between the first shallow trench isolation structure and the second shallow trench isolation structure, and portions of the boundary between the first shallow trench isolation structure and the second shallow trench isolation structure are covered by the first gate structure and the second gate structure.
